(19) United States
(12) Patent Application Publication
(10) Pub. No.: US 2004/0150483 A1
(43) Pub. Date: Aug. 5, 2004

(54) Voltage controlled oscillators with selectable oscillation frequencies and methods for adjusting the same

(76) Inventor: Je-Kwang Cho, Kyungki-do (KR)

Correspondence Address: MYERS BIGEL SIBLEY & SAJOVEC, PO BOX 37428, RALEIGH, NC, 27627, US

(21) Appl. No.: 10/727,031

(22) Filed: Dec. 2, 2003

(30) Foreign Application Priority Data
Jan. 30, 2003 (KR) 2003-6364

(51) Int. Cl. H03B 5/00

(52) U.S. Cl. 331/117 R

(57) ABSTRACT

Voltage controlled oscillators include an amplifier that generates an oscillation output signal having an oscillation frequency based on an applied inductance and capacitance. An inductor coupled to the amplifier applies the inductance. A switched capacitor circuit includes a plurality of switches and capacitors selectably coupled to the amplifier through respective ones of the switches. A switched varactor circuit includes a plurality of switches and varactors selectably coupled to the amplifier through respective ones of the switches. The capacitances of the varactors are responsive to an applied control voltage. A control circuit is configured to select ones of the switches of the capacitor circuit and of the varactor circuit and to provide a selected control voltage to the varactor circuit to apply a desired capacitance to the amplifier.

### RELATED APPLICATION

This application claims the benefit of Korean Patent Application No. 10-2003-0006364, filed on Jan. 30, 2003, which is incorporated herein in its entirety by reference.

### BACKGROUND OF THE INVENTION

The present invention relates to voltage controlled oscillators, and more particularly, to an inductor-capacitor (LC) voltage controlled oscillator and methods of using the same.

It is known to use a voltage controlled oscillator (VCO) in mobile wireless communication systems. The VCO in such devices may be an inductor-capacitor (LC) voltage controlled oscillator, which may include an inductor and a varactor. Such an LC voltage controlled oscillator generally has frequency variable characteristics and low noise characteristics suitable for use as a local oscillator in mobile communication systems.

As mobile communication devices have been introduced supporting multi-band and multi-mode characteristics, there has been an increased need for related Integrated Circuits (IC) for communications devices with an increased working frequency band of a voltage controlled oscillator. The voltage controlled oscillator may be used, for example, as a local oscillator in a Phase-Locked Loop (PLL) of a mobile communication device and also may used in an offset PLL of a system transmission site, such as a Global System for Mobile Communications (GSM) site. Therefore, the stability of the voltage controlled oscillator must be sufficient to stably operate the PLL. It is known to provide an improvement in the stability of the PLL by changing a gain of the voltage controlled oscillator within a limited range at a wide working frequency band.

FIG. 1 is a schematic circuit diagram of a conventional LC voltage controlled oscillator. As shown in FIG. 1, a voltage applied to the conventional LC voltage controlled oscillator changes the capacitance Cᵥ of a varactor, which changes the overall capacitance of the oscillator while the inductance is substantially unchanged. As a result, a resonance frequency of the LC voltage controlled oscillator changes and the LC voltage controlled oscillator operates responsive to application of the voltage. Also shown in FIG. 1 are a parasitic resistance component R and a capacitance component C_{load}, which exist at an output terminal of the oscillator that outputs an oscillation (oscillating) signal Vo.

It is also known to use an LC voltage controlled oscillator that simultaneously uses a switched capacitor and a varactor in mobile communication systems. Such an oscillator is described, for example, in U.S. Pat. No. 6,211,745.

For the LC voltage controlled oscillator shown in FIG. 1, the bandwidth of the oscillating frequency typically may be enlarged by increasing a range of the capacitance Cᵥ of the varactor. However, a gain of the oscillator generally must be increased to widen the range of the capacitance Cᵥ. An excessive increase in the gain of the oscillator may aggravate the noise characteristics of the oscillator. In addition, as such oscillators are incorporated in integrated circuit (IC) devices designed to operate at a low voltage, there is typically a limit to how much the frequency bandwidth of oscillators using a varactor can be increased. Furthermore, as a switched capacitor and a varactor are simultaneously used to enlarge the frequency bandwidth of such a conventional LC voltage controlled oscillator, a resulting increase in the total number of switched capacitors, while increasing the bandwidth of the working frequency, ma also cause a fluctuation of the gain of the oscillator. This may, in turn, deteriorate the stability of the oscillator in a PLL.

### SUMMARY OF THE INVENTION

According to some embodiments of the present invention, voltage controlled oscillators include an amplifier that generates an oscillation output signal having an oscillation frequency based on an applied inductance and capacitance. An inductor coupled to the amplifier applies the inductance. A switched capacitor circuit includes a plurality of switches and capacitors selectably coupled to the amplifier through respective ones of the switches. A switched varactor circuit includes a plurality of switches and varactors selectably coupled to the amplifier through respective ones of the switches. The capacitances of the varactors are responsive to an applied control voltage. A control circuit is configured to select ones of the switches of the capacitor circuit and of the varactor circuit and to provide a selected control voltage to the varactor circuit to apply a desired capacitance to the amplifier.

In other embodiments of the present invention, the control circuit is configured to select designated ones of the switches of the capacitor circuit and of the varactor circuit and to apply a designated control voltage to set the oscillation frequency while limiting a variation in gain of the amplifier across a range of oscillation frequencies. The amplifier may be a trans-conductance amplifier and the oscillator may also include a non-switched varactor coupled to the amplifier. The non-switched varactor may have a capacitance responsive to the control voltage.

In further embodiments of the present invention, the control circuit is configured to set the switches of the switched varactor circuit and the switched capacitor circuit substantially simultaneously to limit variations in a gain of the amplifier when changing the oscillation frequency. The amplifier may be a bipolar transistor or a field effect transistor. The plurality of capacitors of the switched capacitor circuit, respectively, may have capacitance values C_{SW}, 2¹C_{SW}, . . . , and 2⁽ⁿ⁻¹⁾C_{SW}, wherein C_{SW} is the capacitance value of a lowest capacitance one of the plurality of capacitors and wherein n is a number of capacitors in the plurality of capacitors of the switched capacitor circuit. The plurality of varactors may have capacitance values C_{V,SW}, 2¹C_{V,SW}, . . . , and 2ⁿ⁻¹C_{V.SW}, where C_{V.SW} is the capacitance value of a lowest capacitance one of the plurality of varactors and wherein n is a number of varactors in the plurality of varactors. The varactors may have pn-junction diode structures.

In other embodiments of the present invention, the control circuit is configured to switch on and/or off the switches of the switched varactor circuit such that the capacitances of the varactors of the switched varactor unit connected to switched ones of the switches of the switched varactor circuit satisfy the following equation:

C_{v,k}=(A₀+k A_{sw})Cⱼₒ(1+V_{cnt}/φ)^{-m}

wherein k is a decimal value of a binary digital control signal for selecting ones of the plurality of switches of the switched varactor circuit, C_{v,k} is a sum of the capacitances of the varactors coupled through selected switches, A₀ is a capacitance area of a non-switched varactor coupled to the amplifier, A_{sw} is a unit capacitance area of a switched varactor, V_{cnt} is the control voltage, Cⱼₒ is a capacitance value per a unit area of a varactor when an inverse bias voltage is 0, φ is a built-in potential and m is a coefficient that represents varactor characteristics. The unit capacitance area of the switched varactor A_{sw} is selected to minimize the rate of variation in a gain of the oscillator based on following equations:

$$Q = - \frac{{( 1 + \frac{{C}_{d}}{{C}_{v , k}} )}^{2}}{9} , R = - \frac{27 ( \frac{{C}_{d} + {C}_{sw}}{{C}_{v , k}} ) + 2 {( 1 + \frac{{C}_{d}}{{C}_{v , k}} )}^{3}}{54} , \\ S = \sqrt[3]{R + \sqrt{{Q}^{3} + {R}^{2}}} , T = \sqrt[3]{R - \sqrt{{Q}^{3} + {R}^{2}}} , where ST = - Q , \\ a = {( S + T + ( \frac{1}{3} ) ( 1 + \frac{{C}_{d}}{{C}_{v , k}} ) )}^{3} = \frac{{A}_{0} + ( k + 1 ) {A}_{sw}}{{A}_{0} + k {A}_{sw}} , \\ {A}_{sw} = \frac{{A}_{0} ( a - 1 )}{k ( 1 - a ) + 1}$$

where Cd is a load capacitance value that is parasitic on an output terminal of the oscillation output signal, k is a decimal value of a binary digital control signal for selecting ones of the plurality of switches of the switched varactor circuit, C_{v,k} is a sum of the capacitances of varactors coupled through selected ones of the switches, C_{sw} is a capacitance value of switched capacitors, A₀ is a capacitance area of the non-switched varactor and A_{sw} is a unit capacitance area of a switched varactor.

In other embodiments of the present invention, phase-locked loop circuits are provided including a voltage controlled oscillator according to one of the embodiments described above.

In further embodiments of the present invention, methods of changing the oscillation frequency of a voltage controlled oscillator having an amplifier with an inductor, a switched capacitor circuit and a switched varactor unit coupled thereto that determine the oscillation frequency are provided. A capacitance of the switched varactor circuit as seen by the amplifier is changed by selecting a desired control voltage input to the switched varactor unit that determines a capacitance of varactors included in the switched varactor circuit and by selecting ones of the varactors included in the switched varactor circuit to couple to the amplifier. A capacitance of the switched capacitor circuit as seen by the amplifier is changed by selecting ones of a plurality of capacitors included in the switched capacitor circuit to couple to the amplifier. An amplified oscillation signal having an oscillation frequency based on the changed capacitance of the switched varactor circuit and the changed capacitance of the switched capacitor circuit is generated from the amplifier.

According to further embodiments of the present invention, a voltage controlled oscillator includes a trans-conductance amplifier that generates an amplified oscillation signal having oscillation frequency, which change in response to changes in input whole inductance and capacitance, and outputs the signal to an oscillation signal output terminal; an inductor that supplies the whole inductance; a non-switched varactor whose capacitance changes in accordance with a change in a control voltage applied to a control voltage input terminal, the capacitance of the non-switched varactor resulting in a change in the whole capacitance; a switched capacitor unit that includes a plurality of digital switches controlled by a control circuit, and capacitors connected to the digital switches, respectively, the capacitances of the capacitors connected to the switched digital switches being adjusted to change the whole capacitance; and a switched varactor unit that includes a plurality of digital switches, and varactors that are connected to the digital switches, respectively, and whose capacitances change in accordance with a change in the control voltage, the capacitances of the varactors connected to the switched digital switches being adjusted to change the whole capacitance.

The trans-conductance amplifier may include a bipolar transistor or a field effect transistor. The switched capacitor unit may include the plurality of capacitors, the capacitances of which are assigned with binary weights to obtain capacitance values C_{SW}, 2¹C_{SW}, . . . , and 2⁽ⁿ⁻¹⁾C_{SW}, C_{SW} denoting the capacitance value of the lowest-rank capacitor.

The switched varactor unit may include the plurality of varactors, the capacitances of which are assigned with binary weights to obtain capacitance values C_{V,SW}, 2¹C_{V,SW}, . . . , and 2ⁿ⁻¹C_{V,SW}, C_{V.SW} denoting the capacitance value of the lowest-rank varactor. The varactors included in the switched varactor unit may change in accordance with a change in the control voltage. In particular, the varactors included in the switched varactor unit may have pn-junction diode structures such that their capacitances change in accordance with a change in the control voltage.

According to other embodiments of the present invention, methods of operating a voltage controlled oscillator include supplying a whole inductance using an inductor included in the oscillator; changing the whole capacitance of the oscillator by controlling the capacitance of a varactor unit included in the oscillator in accordance with a change in a control voltage input to a control voltage input terminal; changing the whole capacitance of the oscillator by controlling a sum of the capacitances of a plurality of capacitors of a switched capacitor unit connected to a plurality of switched digital switches, the plurality of digital switches being controlled by a control circuit; changing the whole capacitance of the oscillator by controlling a sum of the capacitances of a plurality of varactors of a switched varactor unit connected to the switched digital switches, the capacitances of the varactors changing in accordance with a change in the control voltage and generating an amplified oscillation signal having oscillation frequency, which changes in response to changes in the input whole inductance and capacitance, using a trans-conductance amplifier included in the oscillator, and outputting the signal to an oscillation signal output terminal.

In a voltage controlled oscillator according to some embodiments of the present invention, a trans-conductance (Gm) amplifier generates an amplified oscillation signal Vₒ having oscillation frequency, which changes in response to changes in a whole inductance and a whole capacitance, and outputs the signal V₀ to an oscillation signal output terminal, i.e., a Vₒ node.

### BRIEF DESCRIPTION OF THE DRAWINGS

FIG. 1 is a schematic circuit diagram illustrating a conventional inductor-capacitor (LC) voltage controlled oscillator;

FIG. 2 is a circuit diagram illustrating a voltage controlled oscillator according to some embodiments of the present invention;

FIG. 3 is a graph illustrating variation in the frequency of the voltage controlled oscillator of FIG. 2 versus a control voltage Vcnt;

FIG. 4 is a graph illustrating variation in the gain of the voltage controlled oscillator of FIG. 2 versus a control voltage Vcnt;

FIG. 5 is a graph illustrating variation in the gain of the voltage controlled oscillator of FIG. 2 versus a a digital control signal at a fixed control voltage Vcnt;

FIG. 6 is a graph illustrating variation in the gain of the voltage controlled oscillator of FIG. 2 versus a unit area of a switched varactor unit and the digital control signal;

FIG. 7 is a circuit diagram of a voltage controlled oscillator implemented as a complementary metal oxide semiconductor (CMOS) according to some embodiments of the present invention; and

FIG. 8 is a circuit diagram of the capacitor bank unit illustrated in FIG. 7.

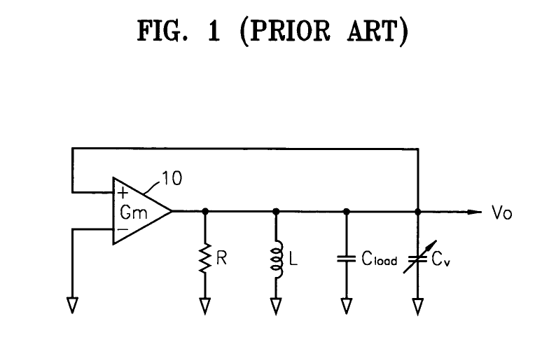

### DETAILED DESCRIPTION

The present invention now will be described more fully with reference to the accompanying drawings, in which embodiments of the invention are shown. This invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like reference numerals refer to like elements throughout.

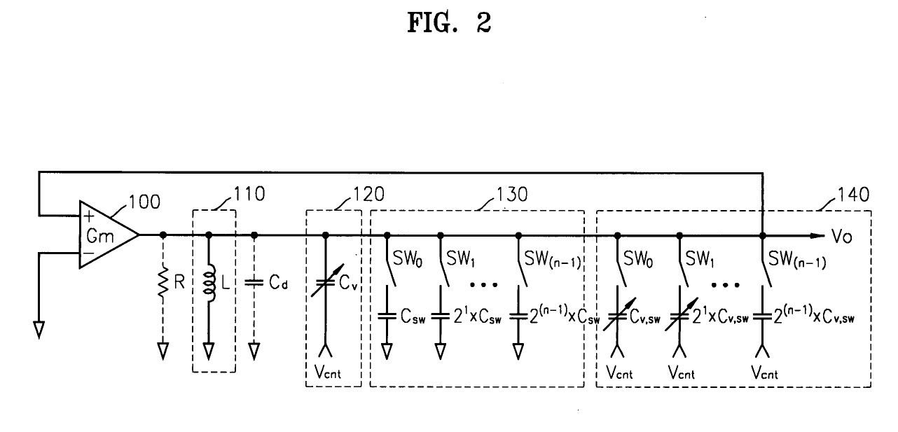

FIG. 2 is a circuit diagram of a voltage controlled oscillator according to some embodiments of the present invention. As shown in FIG. 2, the voltage controlled oscillator includes a trans-conductance (Gm) amplifier 100, an inductor 110, a non-switched varactor unit 120, a switched capacitor unit 130 and a switched varactor unit 140. In FIG. 2, C_{d} denotes a further capacitance component that represents a parasitic load on an oscillation signal output terminal of the voltage controlled oscillator and R denotes a resistance component that is also parasitic on the oscillation signal output terminal.

The trans-conductance (Gm) amplifier 100 generates an amplified oscillation signal Vₒ having oscillation frequency that changes based on an input overall inductance and capacitance of the circuit and outputs the oscillation signal Vₒ to the oscillation signal output terminal. For the embodiments of FIG. 2, the trans-conductance (Gm) amplifier 100 may include a bipolar transistor and/or may include a field effect transistor (FET).

The inductor 110 provides the overall inductance of the VCO of FIG. 2 (i.e., represents the entire inductance of the VCO). The capacitance of the non-switched varactor unit 120 changes when a control voltage V_{cnt} applied to a control voltage input terminal changes, thereby changing the total effective capacitance of the VCO.

The switched capacitor unit 130 as shown in FIG. 2 includes a plurality of digital switches SW₀ through SWₙ₋₁ that are controlled by a control circuit and a plurality of capacitors connected to the switches SW₀ through SWₙ₋₁, respectively. The capacitance of the switched capacitor unit 130 is the sum of the capacitances of the selected capacitors connected VCO by the switched digital switches SW₀ through SWₙ₋₁. The overall (whole) capacitance of the VCO depends on the capacitance of the switched capacitor unit 130 and the other capacitances as described herein. As shown in the embodiments of FIG. 2, binary weights are applied to capacitance values of the capacitors of the switched capacitor unit 130 and, thus, their capacitance values are C_{SW}, 2¹C_{SW}, . . . , 2ⁿ⁻¹C_{SW}. As such, C_{SW} denotes the capacitance value of the lowest-rank capacitor.

The switched varactor unit 140 includes a plurality of digital switches SW₀ through SWₙ₋₁ and a plurality of varactors connected to the digital switches SW₀ through SWₙ₋₁, respectively. A change in the control voltage V_{cnt} results in a change in the capacitances of the varactors. The capacitance of the switched varactor unit 140 is determined by a sum of the capacitances of the selected varactors connected to VCO by the switched digital switches SW₀ through SWₙ₋₁. The overall capacitance of the VCO depends on the capacitance of the switched varactor unit 140 and the other capacitances as described herein. As shown in the embodiments of FIG. 2, binary weights are applied to capacitance values of the varactors of the switched varactor unit 140 and, thus, their capacitance values are C_{V,SW}, 2¹C_{V,SW}, . . . , and 2ⁿ⁻¹C_{V,SW}. C_{V,SW} denotes the capacitance value of the lowest-rank varactor. The varactors of the switched varactor unit 140 are changed responsive to a change in the control voltage V_{cnt}. In particular, the varactors may have pn-junction diode structures and their capacitances may change responsive to a change in the control voltage V_{cnt}.

The control circuit generates a digital control signal for switching (opened/closed) the digital switches SW₀ through SWₙ₋₁ included in the switched capacitor unit 130 and the switched varactor unit 140 so as to adjust the capacitance of the switched varactor unit 140, thereby controlling the total capacitance of the oscillator, which may minimize variation in a gain of the oscillator.

More specifically, in some embodiments of the present invention, switching on or off of digital switches SW₀ through SWₙ₋₁ is controlled such that a sum of the capacitances of the capacitors connected to switched digital switches satisfies Equation (4) below. A gain of the oscillator may be computed using Equations (1) and (2) below and the unit capacitance area of a switched varactor may be computed using Equation (3) below.

$$\begin{matrix}F = \frac{1}{2 π \sqrt{LC}} , \\ C = Cv + k \times Csw + Cd , \\ Cv = A {{C}_{jo} ( 1 + {V}_{cnt} / φ )}^{- m} , \\ \begin{matrix}{K}_{vco} = \frac{\partial F}{\partial {V}_{cnt}} \\ = \frac{\partial F}{\partial {C}_{v}} \cdot \frac{\partial {C}_{v}}{\partial {V}_{cnt}} \\ = \frac{1}{4 π \sqrt{L}} {( {C}_{d} + k {C}_{sw} + {C}_{v} )}^{- \frac{3}{2}} \\ ( - m ) A . {{C}_{jo} ( 1 + {V}_{cnt} / φ )}^{- ( m + 1 )} \\ = \frac{A {C}_{jo} m}{4 π \sqrt{L}} {( {C}_{d} + k {C}_{sw} + {C}_{v} )}^{- \frac{3}{2}} \\ {( 1 + {V}_{cnt} / φ )}^{- ( m + 1 )} ( 1 / φ )\end{matrix}\end{matrix} \} \qquad ( 1 )$$

wherein F denotes oscillation frequency; L denotes an inductance value of an inductor; C denotes a total conductance value; C_{d} denotes a load capacitance value that is parasitic on an oscillation signal output terminal; k denotes a decimal value of a binary digital control signal value, ranging from 0 to 2ⁿ⁻¹; Cᵥ denotes a sum of the capacitance values of the varactors connected to switched digital switches SW₀ through SWₙ₋₁; C_{SW} denotes a capacitance value of a switched capacitor; K_{vco} denotes a gain of the oscillator; A denotes a capacitance area of a varactor; V_{cnt} denotes an input control voltage; Cⱼₒ denotes a capacitance value per a unit area of a varactor when an inverse bias voltage is 0; φ denotes a built-in potential and m denotes a coefficient that represents varactor characteristics.

$${K}_{vco , k} = \frac{( {A}_{0} + k {A}_{sw} ) {C}_{jo} m}{φ 4 π \sqrt{L}} {( {C}_{d} + k {C}_{sw} + {C}_{vk} )}^{- 3 / 2} \\ {( 1 + {V}_{cnt} / φ )}^{- ( m + 1 )} ( 1 / φ ) \qquad ( 2 )$$

wherein A₀ denotes a capacitance area of a non-switched varactor and A_{sw} denotes a unit capacitance area of a switched varactor.

$$\begin{matrix}Q = - \frac{{( 1 + \frac{{C}_{d}}{{C}_{v , k}} )}^{2}}{9} , R = - \frac{27 ( \frac{{C}_{d} + {C}_{sw}}{{C}_{v , k}} ) + 2 {( 1 + \frac{{C}_{d}}{{C}_{v , k}} )}^{3}}{54} , \\ S = \sqrt[3]{R + \sqrt{{Q}^{3} + {R}^{2}}} , T = \sqrt[3]{R - \sqrt{{Q}^{3} + {R}^{2}}} , \\ where ST = - Q , \\ a = {( S + T + ( \frac{1}{3} ) ( 1 + \frac{{C}_{d}}{{C}_{v , k}} ) )}^{3} = \frac{{A}_{0} + ( k + 1 ) {A}_{sw}}{{A}_{0} + k {A}_{sw}} , \\ {A}_{sw} = \frac{{A}_{0} ( a - 1 )}{k ( 1 - a ) + 1}\end{matrix} \} \qquad ( 3 )$$

where C_{d} denotes a load capacitance value that is parasitic on the oscillation signal output terminal; k denotes a decimal value of a binary digital control signal value; C_{v,k} denotes a sum of the capacitance values of varactors connected through switched digital switches SW₀ through SWₙ₋₁; C_{sw} denotes a capacitance value of switched capacitors; A₀ denotes a capacitance area of a non-switched varactor and A_{sw} denotes a unit capacitance area of a switched varactor.

Equation (3) is based on K_{vco,k}=K_{vco,k+1}, that is, the gain K_{vco,k} of the oscillator in Equation (2) has a constant value regardless of the decimal value k.

The sum C_{v,k} in Equation (3) satisfies Equation (4):

C_{v,k}=(A₀+k A_{sw})Cⱼₒ(1+V_{cnt}/φ)^{-m} (4)

wherein k denotes a decimal value of a binary digital control signal value; C_{v,k} denotes a sum of the capacitance values of varactors connected through switched digital switches SW₀ through SWₙ₋₁; Aₒ denotes a capacitance area of a non-switched varactor; A_{sw} denotes a unit capacitance area of a switched varactor; V_{cnt} denotes an input control voltage; Cⱼₒ denotes a capacitance value per a unit area of a varactor when an inverse bias voltage is 0; φ denotes a built-in potential and m denotes a coefficient that represents varactor characteristics.

As described for the embodiments of FIG. 2 above, the control circuit determines the unit capacitance area A_{sw} of a switched varactor using Equation (3), for example, to reduce and/or minimize a variation in a gain of the oscillator for different values of the decimal value k. Thus, even if a gain of the oscillator decreases due to the capacitance of the switched capacitor unit 130, it may be possible to compensate for the gain change by adjusting the capacitances of the varactors of the switched varactor unit 140. Thus, the gain of the oscillator may be generally maintained over a wide working frequency band.

Thus, for some embodiments of the present invention, the frequency bandwidth and gain of the oscillator may be maintained even with a wide frequency band regardless of the number of capacitors of the switched capacitor unit and an increase in their capacitances. As such, the oscillator may operate stably in phase-locked loop (PLL) circuit.

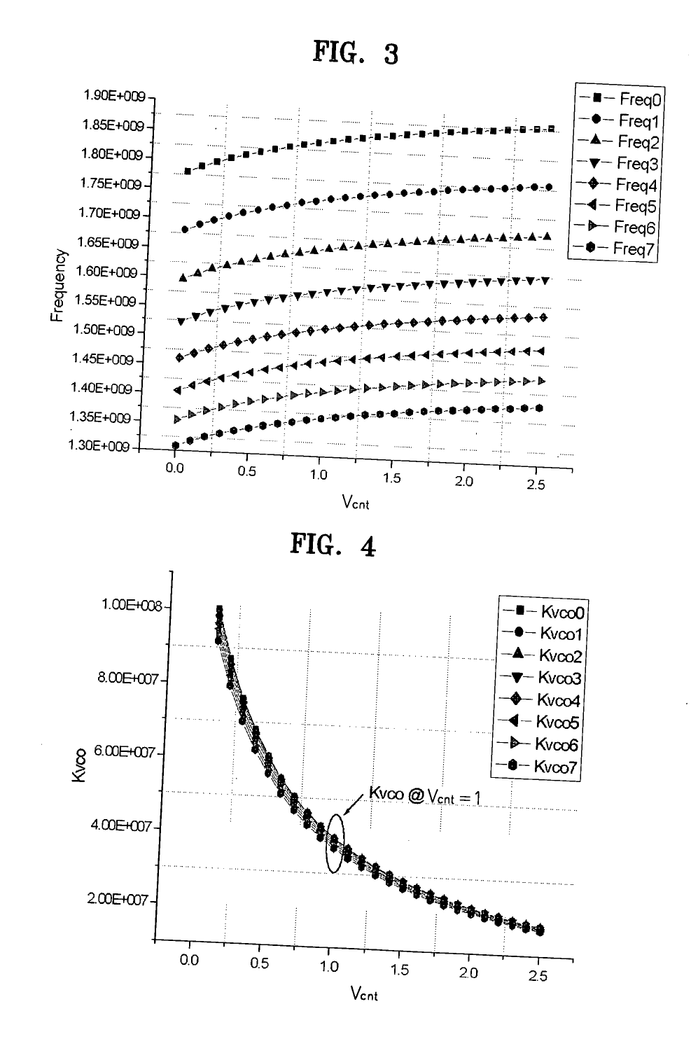

FIG. 3 is a graph illustrating a variation in the frequency characteristics of the voltage controlled oscillator of FIG. 2 versus a control voltage V_{cnt}. In particular, the graph of FIG. 3 shows the results of a simulation where a variation in the frequency characteristics of the voltage controlled oscillator of FIG. 2 is measured with three digital switches, three capacitors and three varactors. Freq0 through Freq7 indicate frequency characteristics, respectively, when a decimal value k of a binary digital control signal value ranges from 0 to 7. As shown for the embodiments of the present invention illustrated in FIG. 3, the working frequency of the voltage controlled oscillator increases slightly as the control voltage V_{cnt} increases.

FIG. 4 is a graph illustrating a variation in the gain of the voltage controlled oscillator of FIG. 2 versus the control voltage V_{cnt}. The graph of FIG. 4 illustrated the result of a simulation where a variation in the frequency characteristics of the voltage controlled oscillator of FIG. 2 is measured with three digital switches, three capacitors and three varactors. K_{vco}0 through K_{vco}7 indicate the gain of the oscillator, respectively, when a decimal value k of a binary digital control signal value ranges from 0 to 7. As shown in FIG. 4, the gain of a voltage controlled oscillator for the illustrated embodiments of the present invention is almost uniformly maintained regardless of working frequency for a control voltage V_{cnt}.

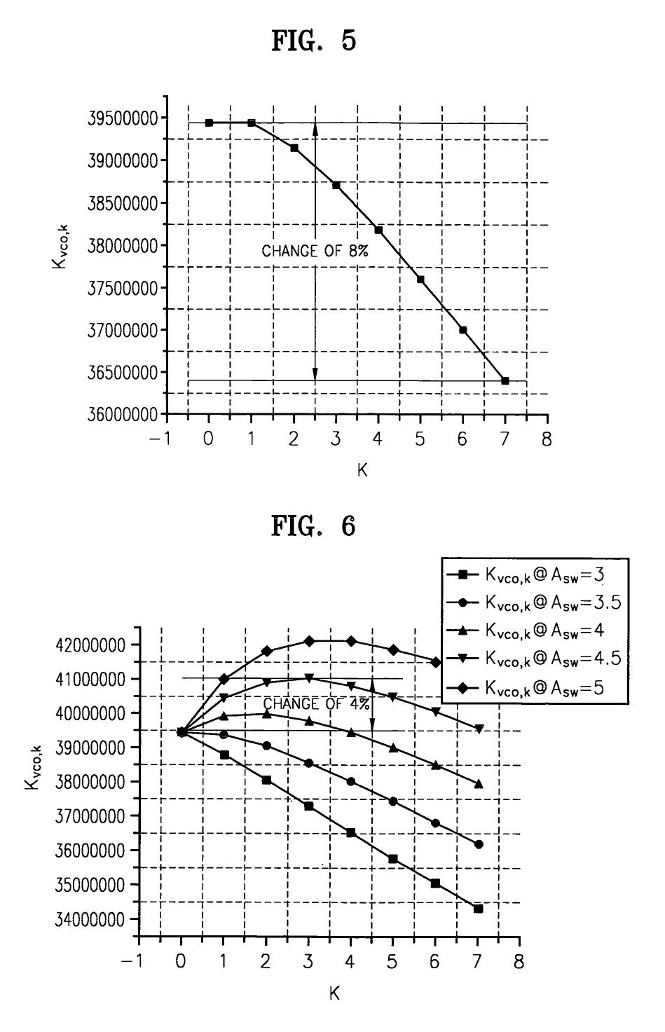

FIG. 5 is a graph illustrating a variation in a gain of the voltage controlled oscillator of FIG. 2 with respect to a digital control signal value when the control voltage V_{cnt} is fixed. The graph of FIG. 5 illustrates the result of a simulation where a variation in a gain of the voltage controlled oscillator of FIG. 2 is measured with three digital switches, three capacitors and three varactors when a decimal value k of a binary digital control signal value ranges from 0 to 7. As shown in FIG. 5, the rate of variation in a gain of a voltage controlled oscillator for the illustrated embodiments of the present invention is very small when the decimal value k is small but increases somewhat as the decimal value k becomes larger. As shown in FIG. 5, when the decimal value k changes in a range from 0 to 7, the rate of variation in gain of the oscillator is 8%, which, in the context of the present invention, is minimal.

FIG. 6 is a graph illustrating a variation in a gain of the voltage controlled oscillator of FIG. 2 when a unit area A_{sw} of a switched varactor and a digital control signal value change. The graph of FIG. 6 illustrates the result of a simulation where a variation in a gain of the voltage controlled oscillator of FIG. 2 is measured with three digital switches, three capacitors and three varactors when a decimal value k of a binary digital control signal value changes from 0 to 7. As previously discussed, A_{sw} denotes a unit capacitance area of a switched varactor. FIG. 6 illustrates the gains K_{vco,k} of the oscillator when the capacitance areas A_{sw} are 3.5, 4, 4.5, and 5. For some embodiments of the present invention, the capacitance area A_{sw} is 4.5, where, as shown in FIG. 6, the rate of variation in gain of the oscillator is small, i.e., about 4%.

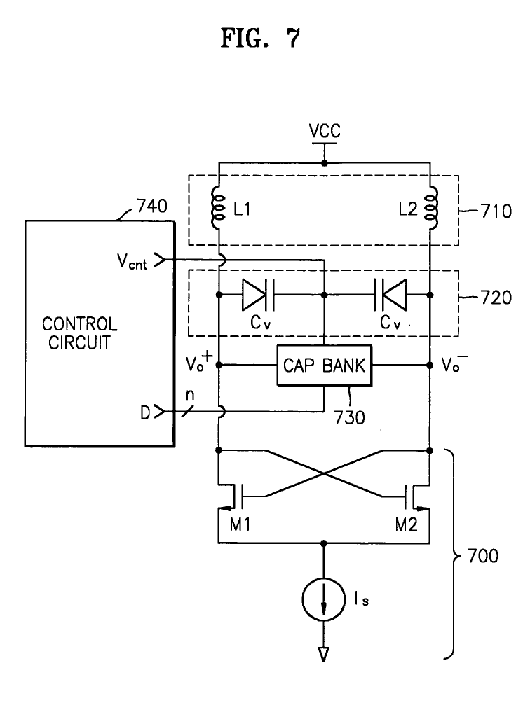

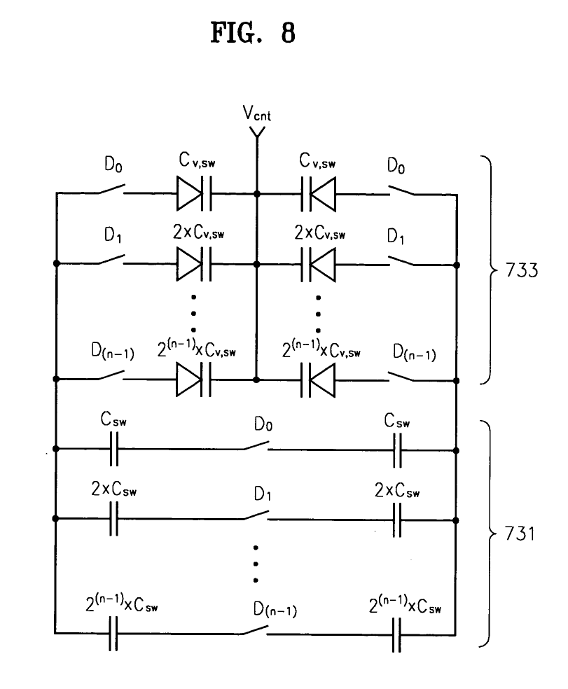

FIG. 7 is a circuit diagram of a voltage controlled oscillator according to some embodiments of the present invention implemented as a complementary metal oxide semiconductor (CMOS). FIG. 8 is a circuit diagram of embodiments of a capacitor bank 730 illustrated in FIG. 7.

Referring now to FIG. 7, the illustrated oscillator includes a trans-conductance (Gm) amplifier 700, an inductor 710, a non-switched varactor unit 720 and the capacitor bank 730. As shown in the embodiments of FIG. 8, the capacitor bank 730 includes a switched capacitor unit 731 and a switched varactor unit 733. The operations of these elements are generally the same as those of the corresponding components shown in the embodiments of FIG. 2 and, thus, they will not be described further herein. The operation and structure of the voltage controlled oscillator shown in FIGS. 7 and 8 is generally equivalent to those of the voltage controlled oscillator of FIG. 2, except that the capacitor bank 730 is included and the switched capacitor unit 731 and the switched varactors 733 are incorporate in the capacitor bank 730.

As shown in FIG. 8, D₀ through Dₙ₋₁ denote signals for switching on or off a plurality of digital switches included in the switched varactor unit 733. The signals D₀ through Dₙ₋₁ are generated by a control circuit 740, such as described with reference to FIG. 2. For the voltage controlled oscillator of FIGS. 7 and 8, the trans-conductance (Gm) amplifier 700 generates an amplified oscillation signals V₀⁺ and V₀⁻ whose oscillation frequencies change in response to input inductances L1 and L2 and the total capacitance of the oscillator, in other words, the sum of the capacitance Cᵥ of the non-switched varactor unit 720 and the capacitance of the capacitor bank 730. The oscillation signals V₀⁺ and V₀⁻ are output to oscillation signal output terminals, i.e., nodes V₀⁺ and V₀⁻.

As described with reference to FIG. 2, the control circuit 730 generates the signals D₀ through Dₙ₋₁ that control switching on or off of the digital switches so as to adjust the capacitance area of the switched varactor unit 733, thereby controlling the overall capacitance of the oscillator, which may reduce or minimize the rate of variation in gain of the oscillator.

As also described with reference to FIG. 2, switching on or off of digital switches may be controlled such that the capacitance area of the switched varactor unit is adjusted to minimize the rate of variation in the gain of the oscillator. A gain of the oscillator may be computed using Equations (1) and (2) and the unit capacitance area of a switched varactor may be computed using Equation (3). The sum C_{v,k} in Equation (3) satisfies Equation (4). Equation (3) is based on K_{vco,k}=K_{vco,k+1}, that is, the gain K_{vco,k}of the oscillator in Equation (2) has a substantially fixed value regardless of the decimal value k. However, unlike in the oscillator of FIG. 2, the switched capacitor unit 731 and the switched varactor unit 733 of FIGS. 7 and 8 may have symmetrical structures. Therefore, the capacitance of each of them in Equations (1) through (4) corresponds to the one-side total capacitance of respective switched capacitors and varactors.

As described above, a voltage controlled oscillator according to embodiments of the present invention includes a trans-conductance (Gm) amplifier that generates an amplified oscillation signal V₀ having an oscillation frequency that changes responsive to changes in the total inductance and capacitance of the oscillator and outputs the signal V₀ to an oscillation signal output terminal, i.e., a V₀ node. An inductor supplies the total inductance of the oscillator. The capacitance of a non-switched varactor unit may be changed responsive to a change in a control voltage V_{cnt} applied to an oscillation signal input terminal by the control circuit 730 to change the total capacitance of the oscillator. A switched capacitor unit includes a plurality of digital switches controlled by a control circuit and includes a plurality of capacitors connected to the digital switches, respectively. The capacitance of the switched capacitor unit may be adjusted to equal a sum of the capacitances of the capacitors connected through the switched digital switches to change the total capacitance of the oscillator. The switched varactor unit includes a plurality of digital switches and a plurality of varactors connected to the digital switches. The capacitances of the varactors changes responsive to a change in the control voltage V_{cnt}. The capacitance of the switched varactor unit 140 may also be adjusted to equal a sum of the capacitances of the varactors connected through the switched digital switches to change the total capacitance of the oscillator.

The inductor-capacitor (LC) voltage controlled oscillator in some embodiments of the present invention simultaneously uses switched capacitors and varactors designed such that the capacitances of the varactors change at the same time as the capacitances of the switched capacitors change. Such oscillators may have low-noise characteristics and operate at a wide frequency band even if a low-level supply voltage is applied to an integrated circuit device including the oscillators. Furthermore, the frequency bandwidth and gain of the oscillator in some embodiments of the present invention may be maintained regardless of the number of the switched capacitors or an increase in their capacitances. Therefore, when the oscillator is included in a PLL, the oscillator may be stably operated in such embodiments.

While this invention has been particularly shown and described with reference to various embodiments thereof, it will be understood by those skilled in the art that various changes in form and details may be made therein without departing from the spirit and scope of the invention as defined by the appended claims.

What is claimed is:

1. A voltage controlled oscillator comprising:
an amplifier that generates an oscillation output signal having an oscillation frequency based on an applied inductance and capacitance;
an inductor coupled to the amplifier that applies the inductance;
a switched capacitor circuit including a plurality of switches and capacitors selectably coupled to the amplifier through respective ones of the switches;
a switched varactor circuit including a plurality of switches and varactors selectably coupled to the amplifier through respective ones of the switches, the capacitances of the varactors being responsive to an applied control voltage; and
a control circuit that is configured to select ones of the switches of the switched capacitor circuit and of the switched varactor circuit and to provide a selected control voltage to the varactor circuit to apply a desired capacitance to the amplifier.

2. The voltage controlled oscillator of claim 1 wherein the control circuit is configured to select designated ones of the switches of the capacitor circuit and of the varactor circuit and to apply a designated control voltage to set the oscillation frequency while limiting a variation in gain of the amplifier across a range of oscillation frequencies.

3. The voltage controlled oscillator of claim 1 wherein the amplifier comprises a trans-conductance amplifier and wherein the oscillator further comprises a non-switched varactor coupled to the amplifier, wherein the non-switched varactor has a capacitance responsive to the control voltage.

4. The voltage controlled oscillator of claim 1 wherein the control circuit is configured to set the switches of the switched varactor circuit and the switched capacitor circuit substantially simultaneously to limit variations in a gain of the amplifier when changing the oscillation frequency.

5. The voltage controlled oscillator of claim 1 wherein the amplifier comprises a bipolar transistor or a field effect transistor.

6. The voltage controlled oscillator of claim 1 wherein the plurality of capacitors of the switched capacitor circuit, respectively, have capacitance values C_{SW}, 2¹C_{SW}, . . . , and 2⁽ⁿ⁻¹⁾C_{SW}, wherein C_{SW} is the capacitance value of a lowest capacitance one of the plurality of capacitors and wherein n is a number of capacitors in the plurality of capacitors of the switched capacitor circuit.

7. The voltage controlled oscillator of claim 1 wherein the plurality of varactors have capacitance values C_{V,SW}, 2¹C_{V,SW}, . . . , and 2ⁿ⁻¹C_{V,SW}, where C_{V,SW} is the capacitance value of a lowest capacitance one of the plurality of varactors and wherein n is a number of varactors in the plurality of varactors.

8. The voltage controlled oscillator of claim 1 wherein the varactors have pn-junction diode structures.

9. The voltage controlled oscillator of claim 1 wherein the control circuit is configured to switch on and/or off the switches of the switched varactor circuit such that the capacitances of the varactors of the switched varactor unit connected to switched ones of the switches of the switched varactor circuit satisfy the following equation:
C_{v,k}=(A₀+k A_{sw})Cⱼₒ(1+V_{cnt}/φ)^{-m}
wherein k is a decimal value of a binary digital control signal for selecting ones of the plurality of switches of the switched varactor circuit, C_{v,k} is a sum of the capacitances of the varactors coupled through selected switches, Aₒ is a capacitance area of a non-switched varactor coupled to the amplifier, A_{sw} is a unit capacitance area of a switched varactor, V_{cnt} is the control voltage, Cⱼₒ is a capacitance value per a unit area of a varactor when an inverse bias voltage is 0, φ is a built-in potential and m is a coefficient that represents varactor characteristics; and
wherein the unit capacitance area of the switched varactor A_{sw} is selected to minimize the rate of variation in a gain of the oscillator based on following equations:
$$Q = - \frac{{( 1 + \frac{{C}_{d}}{{C}_{v , k}} )}^{2}}{9} , R = - \frac{27 ( \frac{{C}_{d} + {C}_{sw}}{{C}_{v , k}} ) + 2 {( 1 + \frac{{C}_{d}}{{C}_{v , k}} )}^{3}}{54} , \\ S = \sqrt[3]{R + \sqrt{{Q}^{3} + {R}^{2}}} , T = \sqrt[3]{R - \sqrt{{Q}^{3} + {R}^{2}}} , where ST = - Q , \\ a = {( S + T + ( \frac{1}{3} ) ( 1 + \frac{{C}_{d}}{{C}_{v , k}} ) )}^{3} = \frac{{A}_{0} + ( k + 1 ) {A}_{sw}}{{A}_{0} + k {A}_{sw}} , \\ {A}_{sw} = \frac{{A}_{0} ( a - 1 )}{k ( 1 - a ) + 1}$$
where Cd is a load capacitance value that is parasitic on an output terminal of the oscillation output signal, k is a decimal value of a binary digital control signal for selecting ones of the plurality of switches of the switched varactor circuit, C_{v,k} is a sum of the capacitances of varactors coupled through selected ones of the switches, C_{sw} is a capacitance value of switched capacitors, Aₒ is a capacitance area of the non-switched varactor and A_{sw} is a unit capacitance area of a switched varactor.

10. A phase-locked loop circuit including the voltage controlled oscillator of claim 1.

11. A method of changing the oscillation frequency of a voltage controlled oscillator having an amplifier with an inductor, a switched capacitor circuit and a switched varactor unit coupled thereto that determine the oscillation frequency, the method comprising:
changing a capacitance of the switched varactor circuit as seen by the amplifier by selecting a desired control voltage input to the switched varactor unit that determines a capacitance of varactors included in the switched varactor circuit and by selecting ones of the varactors included in the switched varactor circuit to couple to the amplifier;
changing a capacitance of the switched capacitor circuit as seen by the amplifier by selecting ones of a plurality of capacitors included in the switched capacitor circuit to couple to the amplifier; and
generating from the amplifier an amplified oscillation signal having an oscillation frequency based on the changed capacitance of the switched varactor circuit and the changed capacitance of the switched capacitor circuit.

12. The method of claim 11 wherein changing the capacitances are selected by selecting designated ones of a plurality of switches of the capacitor circuit that couple the capacitors to the amplifier and a of switches of the varactor circuit that couple the varactors to the amplifier and applying a designated control voltage to set the oscillation frequency while limiting a variation in gain of the amplifier across a range of oscillation frequencies.

13. The method of claim 12 wherein changing the capacitances comprises setting the switches of the switched varactor circuit and the switched capacitor circuit substantially simultaneously to limit variations in a gain of the amplifier when changing the oscillation frequency.

14. A voltage controlled oscillator comprising:
a trans-conductance amplifier that generates an amplified oscillation signal having oscillation frequency, which change in response to changes in input whole inductance and capacitance, and outputs the signal to an oscillation signal output terminal;
an inductor that supplies the whole inductance;
a non-switched varactor whose capacitance changes in accordance with a change in a control voltage applied to a control voltage input terminal, the capacitance of the non-switched varactor resulting in a change in the whole capacitance;
a switched capacitor unit that includes a plurality of digital switches controlled by a control circuit, and capacitors connected to the digital switches, respectively, the capacitances of the capacitors connected to the switched digital switches being adjusted to change the whole capacitance; and
a switched varactor unit that includes a plurality of digital switches, and varactors that are connected to the digital switches, respectively, and whose capacitances change in accordance with a change in the control voltage, the capacitances of the varactors connected to the switched digital switches being adjusted to change the whole capacitance.

15. The voltage controlled oscillator of claim 14, wherein the trans-conductance amplifier comprises a bipolar transistor.

16. The voltage controlled oscillator of claim 14, wherein the trans-conductance amplifier comprises a field effect transistor.

17. The voltage controlled oscillator of claim 14, wherein the switched capacitor unit comprises the plurality of capacitors, the capacitances of which are assigned with binary weights to obtain capacitance values C_{SW}, 2¹C_{SW}, . . . , and 2⁽ⁿ⁻¹⁾C_{SW}, C_{SW} denoting the capacitance value of the lowest-rank capacitor.

18. The voltage controlled oscillator of claim 14, wherein the switched varactor unit comprises the plurality of varactors, the capacitances of which are assigned with binary weights to obtain capacitance values C_{V,SW}, 2¹C_{V,SW}, . . . , and 2⁽ⁿ⁻¹⁾C_{V,SW}, C_{V,SW} denoting the capacitance value of the lowest-rank varactor.

19. The voltage controlled oscillator of claim 18, wherein the varactors included in the switched varactor unit are means that change in accordance with a change in the control voltage.

20. The voltage controlled oscillator of claim 18, wherein the varactors included in the switched varactor unit have pn-unction diode structures such that their capacitances change in accordance with a change in the control voltage.

21. The voltage controlled oscillator of claim 14, wherein the control circuit switches on or off the digital switches such that the whole capacitance is adjusted to minimize the rate of variation in a gain of the oscillator.

22. The voltage controlled oscillator of claim 21, wherein switching on or off of the digital switches is controlled such that the capacitances of the varactors of the switched varactor unit connected to switched digital switches satisfy the following equation:
C_{v,k}=(A₀+k A_{sw})Cⱼₒ(1+V_{cnt}/φ)^{-m}
wherein k denotes a decimal value of a binary digital control signal value, C_{v,k} denotes a sum of the capacitances of the varactors connected to switched digital switches, Aₒ denotes a capacitance area of a non-switched varactor, A_{sw} denotes a unit capacitance area of a switched varactor, V_{cnt} denotes an input control voltage, Cⱼₒ denotes a capacitance value per a unit area of a varactor when an inverse bias voltage is 0, φ denotes a built-in potential, and m denotes a coefficient that represents varactor characteristics,
wherein the unit capacitance area of the switched varactor A_{sw} is computed to minimize the rate of variation in a gain of the oscillator using the following equations:
$$Q = - \frac{{( 1 + \frac{{C}_{d}}{{C}_{v , k}} )}^{2}}{9} , R = - \frac{27 ( \frac{{C}_{d} + {C}_{sw}}{{C}_{v , k}} ) + 2 {( 1 + \frac{{C}_{d}}{{C}_{v , k}} )}^{3}}{54} , \\ S = \sqrt[3]{R + \sqrt{{Q}^{3} + {R}^{2}}} , T = \sqrt[3]{R - \sqrt{{Q}^{3} + {R}^{2}}} , where ST = - Q , \\ a = {( S + T + ( \frac{1}{3} ) ( 1 + \frac{{C}_{d}}{{C}_{v , k}} ) )}^{3} = \frac{{A}_{0} + ( k + 1 ) {A}_{sw}}{{A}_{0} + k {A}_{sw}} , \\ {A}_{sw} = \frac{{A}_{0} ( a - 1 )}{k ( 1 - a ) + 1}$$
where Cd denotes a load capacitance value that is parasitic on an oscillation signal output terminal, k denotes a decimal value of a binary digital control signal value, C_{v,k} denotes a sum of the capacitances of varactors connected to switched digital switches, C_{sw} denotes a capacitance value of switched capacitors, Aₒ denotes a capacitance area of a non-switched varactor, and A_{sw} denotes a unit capacitance area of a switched varactor.

23. A method of operating a voltage controlled oscillator, comprising:
supplying a whole inductance using an inductor included in the oscillator;
changing the whole capacitance of the oscillator by controlling the capacitance of a varactor unit included in the oscillator in accordance with a change in a control voltage input to a control voltage input terminal;
changing the whole capacitance of the oscillator by controlling a sum of the capacitances of a plurality of capacitors of a switched capacitor unit connected to a plurality of switched digital switches, the plurality of digital switches being controlled by a control circuit;
changing the whole capacitance of the oscillator by controlling a sum of the capacitances of a plurality of varactors of a switched varactor unit connected to the switched digital switches, the capacitances of the varactors changing in accordance with a change in the control voltage; and
generating an amplified oscillation signal having oscillation frequency, which change in response to changes in the input whole inductance and capacitance, using a trans-conductance amplifier included in the oscillator, and outputting the signal to an oscillation signal output terminal.

24. The method of claim 23, wherein the trans-conductance amplifier comprises a bipolar transistor.

25. The method of claim 23, wherein the trans-conductance amplifier comprises a field effect transistor.

26. The method of claim 23, wherein the switched capacitor unit comprises the plurality of capacitors, the capacitances of which are assigned with binary weights to obtain capacitance values C_{SW}, 2¹C_{SW}, . . . , and 2⁽ⁿ⁻¹⁾C_{SW}, C_{SW} denoting the capacitance value of the lowest-rank capacitor.

27. The method of claim 23, wherein the switched varactor unit comprises the plurality of varactors, the capacitances of which are assigned with binary weights to obtain capacitance values C_{V,SW}, 2¹C_{V,SW}, . . . , and 2⁽ⁿ⁻¹⁾C_{V,SW}, C_{V,SW} denoting the capacitance value of the lowest-rank varactor.

28. The method of claim 23, wherein the varactors included in the switched varactor unit are means that change in accordance with a change in the control voltage.

29. The method of claim 23, wherein the varactors included in switched varactor unit have pn-junction diode structures such that their capacitances change in accordance with a change in the control voltage.

30. The method of claim 23, wherein the control circuit switches on or off the digital switches such that the whole capacitance is controlled to minimize the rate of variation in a gain of the oscillator.

31. The method of claim 23, wherein switching on or off of the digital switches is controlled such that the capacitances of the varactors of the switched varactor unit connected to switched digital switches satisfy the following equation:
C_{v,k}=(A₀+k A_{sw})Cⱼₒ(1+V_{cnt}/φ)^{-m}
wherein k denotes a decimal value of a binary digital control signal value, C_{v,k} denotes a sum of the capacitances of the varactors connected to switched digital switches, Aₒ denotes a capacitance area of a non-switched varactor, A_{sw} denotes a unit capacitance area of a switched varactor, V_{cnt} denotes an input control voltage, Cⱼₒ denotes a capacitance value per a unit area of a varactor when an inverse bias voltage is 0, φ denotes a built-in potential, and m denotes a coefficient that represents varactor characteristics,
wherein the unit capacitance area of the switched varactor A_{sw} is computed to minimize the rate of variation in a gain of the oscillator using the following equations:
$$Q = - \frac{{( 1 + \frac{{C}_{d}}{{C}_{v , k}} )}^{2}}{9} , R = - \frac{27 ( \frac{{C}_{d} + {C}_{sw}}{{C}_{v , k}} ) + 2 {( 1 + \frac{{C}_{d}}{{C}_{v , k}} )}^{3}}{54} , \\ S = \sqrt[3]{R + \sqrt{{Q}^{3} + {R}^{2}}} , T = \sqrt[3]{R - \sqrt{{Q}^{3} + {R}^{2}}} , where ST = - Q , \\ a = {( S + T + ( \frac{1}{3} ) ( 1 + \frac{{C}_{d}}{{C}_{v , k}} ) )}^{3} = \frac{{A}_{0} + ( k + 1 ) {A}_{sw}}{{A}_{0} + k {A}_{sw}} , \\ {A}_{sw} = \frac{{A}_{0} ( a - 1 )}{k ( 1 - a ) + 1}$$
where Cd denotes a load capacitance value that is parasitic on an oscillation signal output terminal, k denotes a decimal value of a binary digital control signal value, C_{v,k} denotes a sum of the capacitances of varactors connected to switched digital switches, C_{s,w} denotes a capacitance value of switched capacitors, Aₒ denotes a capacitance area of a non-switched varactor, and A_{sw} denotes a unit capacitance area of a switched varactor.
